(19) United States
(12) Patent Application Publication
(10) Pub. No.: US 2007/0111491 A1
(43) Pub. Date: May 17, 2007

(54) Process for electroplating metal layer without plating lines after the solder mask process

(76) Inventor: Jun Chung Hsu, Ping-Chen City (TW)

Correspondence Address: LIN & ASSOCIATES INTELLECTUAL PROPERTY, P.O. BOX 2339, SARATOGA, CA, 95070-0339, US

(21) Appl. No.: 11/272,599

(22) Filed: Nov. 13, 2005

(51) Int. Cl. H01L 21/20; H01L 21/302; C25D 5/00

(52) U.S. Cl. 438/584; 438/689; 205/80

(57) ABSTRACT

A process for electroplating a metal layer without the plating lines after the solder masking process is provided, which is characterized in that a ball pad which is on one side of the carrier board is connected to a anchor clamp of an electroplating device via a temporary conductor layer after the solder masking process so that the electric current can flow from the temporary conductor layer to the object to be plated on another side of the circuit board, so as to form the electroplated protective layers on both sides of the carrier board. Then, the temporary conductor layer is removed after electroplating. As a result, no plating lines will occupy the circuit layout area.

### BACKGROUND OF THE INVENTION

1. Field of the Invention

The present invention relates generally to a process for electroplating a metal layer without the plating lines, and in particular to a process for electroplating a metal layer without the plating lines after the solder mask process. The process involves creating a conducting layer on bottom side of substrate (one side only); then, applying the plating resist on bottom side and expose the specific area for metal plating; and next, plating the metal on top & bottom side simultaneously or plating the top side only.

2. The Prior Arts

Because the electronic products nowadays tend to be miniaturized, the design for the carrier board tends to reduce the numbers of the conductor lines on it in order to spare the layout space while tending to improve the electricity of the packaged products and to reduce the noise which is produced during the transmission of the signals. Therefore, the process for electroplating a metal layer on an object to be plated without pulling the plating line has become a major topic for study in industry.

The major methods for electroplating metal layers without the need of plating lines include: NPL, Bottom Plating, FBG(GPP), Selective Gold Plating, EN/IG. However, the above-mentioned methods have some problems as following.

The non-plating line (NPL) technology provides a method for electroplating nickle/gold layer on an electrical connecting pad of a substrate without the need of the layout of plating lines on the substrate. For NPL, The electrical connecting pads on the substrate are electrically connected with each other through the conductive film which covers the surface of the substrate and serves as an electrically conductive path. NPL provides a solution to solve the problem of insufficient circuit layout area due to the disposition of the plating lines, however, it has some drawbacks when applied to a substrate with a high density of circuit layout and fine pitch. In addition, in the case of NPL, and bottom plating, if the layout pattern has independent nets which are disposed on the same layer, the manufacturing process becomes complicated. As a result, the manufacturing cost is increased.

Moreover, NPL apply the conductive film covers the surface the substrate having the isolated pads, and photo resist layer is form over the copper trace and conductive film. Exposing a portion of the conductive film over the isolated pads by photoresist. The exposed portion of the conductive film is removed first then use photo resist again for identify the isolated pad for plating. In briefly, NPL need to remove the conductive film after 1^{st} photo resist image transfer. And, 2^{nd} image transfer is applied after conductive film removed. Besides, NPL process mostly applied before solder mask process and the process are more complicated and higher cost.

Gold pattern plating technology utilizes a conductive layer instead of plating lines to allow electric current to pass through; however, the overall cost of materials is very high as the entire circuit layer (including electrical connecting pads and all conductive circuits) is covered with the Ni/Au metal layer. Moreover, during the latter procedure of circuit patterning, because the circuit layer is entirely covered with the Ni/Au layer the adhesion performance between solder mask is weaker compare with copper vs. solder mask.

Selective gold plating is difficult because the operating window is narrow. Need to apply the photo resist on the top of former photo resist and Also, the occurrence of the permeable plating may happen when the selective gold plating is performed, which can decrease the yield. For the electroless nickel and immersion gold (ENAG) method, the drawbacks of it is that the chemical solution is not easily controlled, the chemical solution sometimes may attack the solder mask. Also, the problems, including black pad, thin edge-effect, and skip-plate may happen. Moreover, the black pad phenomenon can cause poor bondability between the solder balls and the pads so that the solder balls may fall off.

In the methods of FBG, NPL, Bottom Plating, and Selective Gold Plating, the solder resist covers the metal layer because electroplating nickel and gold is performed before the solder mask process. However, the material property of the solder mask greatly differs from that of the metal layer (ex. Ni/Au), stable adhesion between the two is potentially weaker compare with copper, which cause the low adhesion reliability. Another problem is that the solder resist may remain on the surface of the metal layer and contaminate the surface of the metal layer. This kind of contamination can affect the wire bonding quality during the subsequent packaging. Obviously, in IC package technology, the solder mask process should be done before plating nickel and gold in order to solve the problems set forth above.

### SUMMARY OF THE INVENTION

The objective of the present invention is to provide a process for electroplating a metal layer without the plating lines after the solder mask process. In this process, a temporary layer is formed on the ball side of the carrier board, and the electric current for plating, which is provided by the electroplating device, flows from the temporary conductor layer through the circuit layer on the ball side via the blind via or through hole to bump/wirebond side, so as to form the electroplated protective layers formed on both sides (the bump/wirebond side and the ball side) of the carrier board. In such a way, the solder mask process is done before plating nickel and gold, so as to solve the problems set forth above.

To achieve the foregoing objective, the present invention provides a process for electroplating a metal layer without the plating lines after the solder mask process. In the first embodiment, a first plating resist is firstly formed on the bump/wirebond side of the carrier board to cover the solder mask. Then, a temporary conductor layer (TCL) is formed on the ball side of the carrier board to cover the solder mask layer on the ball side. Then, remove the 1^{st} plating resist and a second plating resist pattern is formed on bottom side. Finally, the electric current for plating, which is provided by the electroplating device, flows from the temporary conductor layer through the blind via or mechanical hole to the top layer on the bump/wirebond side, so as to form the electroplated layers on both side simultaneously typically.

In the second embodiment, a temporary conductor layer is directly applied on the ball side of the carrier board after solder mask process in order to electrically connect all the nets which are originally non-conductive with each other. The process in the second embodiment is the same as the process in the first embodiment except without the step of “a first plating resist is firstly formed on the bump/wirebond side of the carrier board to cover the solder resist layer”, and the subsequent step of “remove the 1^{st}” plating resist” in the second embodiment.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIGS. 1A-1G are schematic diagrams showing a process for electroplating a metal layer without the plating lines after the solder masking process in accordance with the present invention.

### DETAILED DESCRIPTION OF THE PREFERRED EMBODIMENT

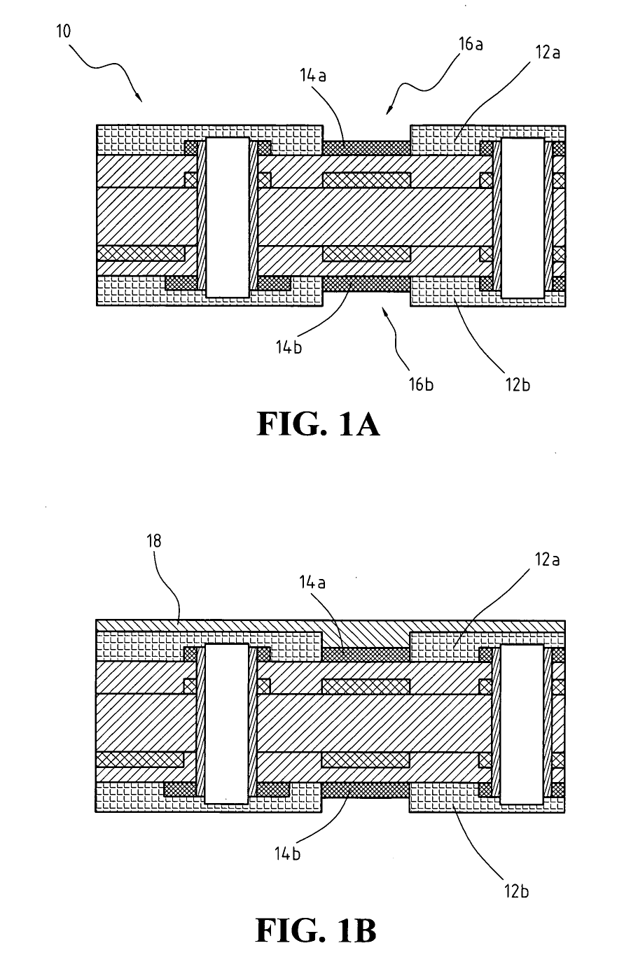

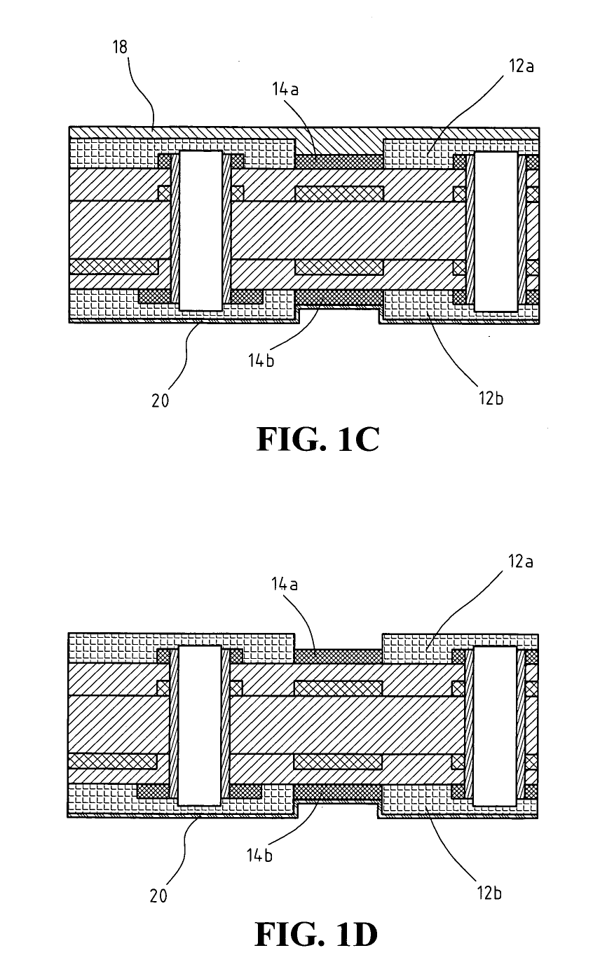

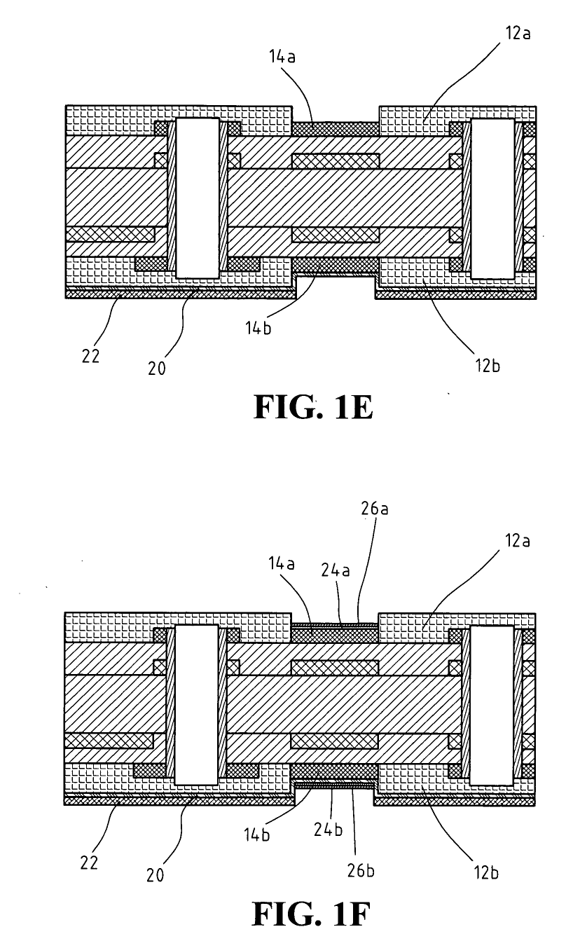

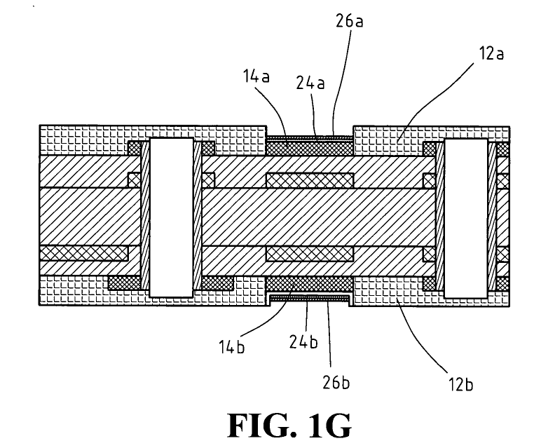

FIGS. 1A-1G are schematic diagrams showing a process for electroplating a metal layer without the plating lines after the solder masking process in accordance with the present invention.

As shown in FIG. 1F, in the process for electroplating a metal layer without the plating lines after the solder mask process in accordance with the present invention, the electroplated protective layers (nickle layers 24a, 24b, and gold layers 26a, 26b, as shown in FIG. 1F) are formed on the circuit layers 14a, 14b, which are respectively disposed on the bump/wirebond side and the ball side of the carrier board 10, by an electroplating process in which the electric currents flow from the circuit layer 14b on the ball side to the circuit layer 14a on the top side via a temporary conductor layer (TCL) 20 formed on the ball side of the carrier board 10. By such a way, the prior electroplating problems can be overcome because the solder mask process is performed before the metal (ex. nickel and gold plating). Meanwhile, the second plating resist 22, and the temporary conductor layer 20 is removed, as shown in FIG. 1G, and thereby the problems caused by the occupation of the plating lines in the circuit layout area can be avoided. The process of the present invention is described as following.

A carrier board 10 on which a solder resist has been applied is provided, as shown in FIG. 1A. The openings 16a, 16b are respectively formed by surrounding the circuit layers 14a, 14b respectively disposed on the bump/wirebond side and the ball side of the carrier board 10 with the solder resist layers 12a, 12b. The solder resist layers 12a, 12b can be solder mask, epoxy resin, or bonding sheets. The circuit layer 14b disposed on the ball side can be ball pad, and the circuit layer 14a disposed on the bump side can be power ring, or bond finger. The structure of the circuit board 10 including the through holes (or blind via) which electrically connect the bump/wirebond side and the ball side of the carrier board 10, and the method for manufacturing it are the same as those of the prior art. Therefore, the structure of the circuit board 10, and the method for manufacturing the same are not mentioned herein. As shown in FIG. 1B, the first plating resist 18 is formed on the bump side of the circuit board 10, and covers the solder resist 12a and the circuit layer 14a within the opening 16a in order to form a temporary conductor layer 20 only on the ball side of the carrier board 10. As shown in FIG. 1C, a temporary conductor layer 20 is formed on the ball side of the circuit board 10, and covers the solder resist 12b and the circuit layer 14a within the opening 16b. However, it is not necessary that the first plating resist 18 is firstly formed on the bump side of the circuit board 10.

In order to perform the process for selectively electroplating the circuit layers 14a, 14b, the plating resist 18 on the bump side is removed, as shown in FIG. 1D, and the circuit layer 14b which is to be electroplated is defined by a second plating resist 22. In other word, a plating resist 22 is formed on the temporary conductor layer 20, which formed on the solder resist layer 12b, on the ball side of the circuit board 10, and the circuit layer 14b can not be covered by the second plating resist 22 if the circuit layer 14b is to be electroplated, as shown in FIG. 1E.

Finally, the temporary conductor layer 20 is connected to the anchor clamp (not shown) of the electroplating device. The electric current for plating, which is provided by the electroplating device, flows from the temporary conductor layer 20 through the circuit layer 14b on the ball side to the circuit layer 14a on the bump side, so as to form the electroplated metal layers on the circuit layer 14a, 14b respectively disposed on the bump/wirebond side and the ball side of the carrier board 10, as shown in FIG. 1F. The electroplated metal layers can be gold layers 26a, 26b, or nickel layers 24a, 24b, or combination thereof. That is, the gold layer 26a and the nickel layer 24a is formed on the bump side, and the gold layer 26b and the nickel layer 24b is formed on the ball side, as shown in FIG. F.

It will be apparent to those skilled in the art that various modifications and variations can be made in the present invention without departing from the spirit or scope of the present invention. Thus, it is intended that the present invention cover the modifications and the variations of this invention provided they come within the scope of the appended claims and their equivalents.

What is claimed is:

1. A process for electroplating a metal layer without a plating line after the solder mask process, comprising:
(a) providing a carrier board after the solder mask process, which respectively has an opening, formed by surrounding a circuit layer with a solder resist, on a bump/wirebond side and a ball side of a carrier board;
(b) forming a temporary conductor layer on the ball side of the carrier board, which covers the solder resist and the circuit layer within the opening on the ball side of the carrier board;
(c) defining a patterned layer to be plated on the ball side of the carrier board by a photoresist;
(d) flowing an electric current for plating from the temporary conductor layer through the circuit layer on the ball side to the circuit layer on the bump/wire bond side, so as to respectively form an electroplated metal layer on the circuit layer disposed on the ball side and the circuit layer disposed on the bump side; and
(e) removing the second plating resist, and the temporary conductor layer.

2. The process as claimed in claim 1, further includes a step of forming a plating resist on the bump side of the circuit board, which covers the solder resist and the circuit layer within the opening, just after step (a), and a step of removing the plating resist on the bump side just after step (b).

3. The process as claimed in claim 1, wherein the electroplated metal layer is a gold layer, a nickel layer, or combination thereof, or other metal layer.
